(19) United States
(12) Patent Application Publication
(10) Pub. No.: US 2026/0130235 A1
(43) Pub. Date: May 7, 2026

(54) Package with Epitaxial Layer of Electronic Component Spaced from a Front-side Connection Body by less than 50 μm

(71) Applicant: Infineon Technologies AG, Neubiberg (DE)

(72) Inventors: Marcus Böhm, Mintraching (DE); Horst Theuss, Wenzenbach (DE); Saurabh Roy, Villach (AT); Markus Gröner, München (DE); Max Falkowski, Ottobrunn (DE); Sergey Ananiev, Unterhaching (DE); Ralf Otremba, Kaufbeuren (DE); Alexander Heinrich, Bad Abbach (DE); Evelyn Napetschnig, Villach (AT); Hans-Joachim Schulze, Taufkirchen (DE)

(21) Appl. No.: 19/377,723

(22) Filed: Nov. 3, 2025

(30) Foreign Application Priority Data
Nov. 4, 2024 (DE) 102024132055.9

(51) Int. Cl. H01L 23/00; H01L 23/495

(52) U.S. Cl. CPC H10W 70/417; H10W 72/07331; H10W 72/07336; H10W 72/07631; H10W 72/07655; H10W 72/252; H10W 72/352; H10W 72/871; H10W 72/884; H10W 72/886; H10W 90/726; H10W 90/736; H10W 90/756; H10W 90/766

(57) ABSTRACT

A package includes an at least partially electrically conductive front-side connection body and an electronic component having an epitaxial layer and being assembled with the front-side connection body. A distance between the epitaxial layer and the front-side connection body is less than 50 μm. A method of manufacturing the package is also described.

### TECHNICAL FIELD

Various embodiments relate generally to a package and a method of manufacturing a package.

### BACKGROUND

Packages may be denoted as electronic components with electrical connections extending out of the package and being mountable on an electronic periphery, for instance on a printed circuit board.

Packaging cost is an important driver for the industry. Related with this are performance, dimensions and reliability. The different packaging solutions are manifold and have to address the needs of the application.

In a transistor-type electronic component of a package, Rdson is a quality parameter which stands for drain-source on resistance. For example, Rdson may be an indication for the total resistance between the drain and the source in a field-effect transistor, such as a metal oxide semiconductor field-effect transistor (MOSFET) or a junction field-effect transistor (JFET, i.e. a field-effect transistor which may be exclusively voltage-controlled and which may be used for example as electrically controlled switch or resistor), when being in an ‘on’ state. In particular, Rdson may be used as a basis for a maximum current rating of the electronic component and is also associated with current loss. To put it shortly, the lower the Rdson, the better.

However, Rdson of conventional packages may be high.

### SUMMARY

There may be a need for a package with high electrical performance. In particular, there may be a need for a package with low drain-source on resistance.

According to an exemplary embodiment, a package is provided which comprises an at least partially electrically conductive front-side connection body, and an electronic component having an epitaxial layer and being assembled with the front-side connection body, wherein a distance between the epitaxial layer and the front-side connection body is less than 50 μm.

According to another exemplary embodiment, a method of manufacturing a package is provided, wherein the method comprises assembling an at least partially electrically conductive front-side connection body with an electronic component having an epitaxial layer, and arranging the front-side connection body with respect to the electronic component so that a distance between the epitaxial layer and the front-side connection body is less than 50 μm.

According to an exemplary embodiment, a package (which may be a semiconductor power package) may be equipped with a partially or entirely electrically conductive front-side connection body (such as a clip, a leadframe structure or another more generic substrate) establishing a connection with a front-side (at which an active region may be formed) of an electronic component. Said electronic component may comprise an epitaxial layer or active region facing the front-side connection body. A connection between the front-side connection body and the electronic component may be established, for instance, by soldering or sintering. Advantageously, a distance between the epitaxial layer and the front-side connection body may be less than 50 μm. It has been found that such a small distance between active region and connection body at the front-side of the electronic component (for example using common interconnect technologies such as soldering, sintering or (more specifically) diffusion soldering) may create a considerable amount of mechanical strain at the front-side of the electronic component which may lead to a significant decrease of the drain-source on resistance. Thus, a package may be obtained which has a low Rdson value and consequently an excellent maximum current rating as well as low current loss. Also in embodiments in which the electronic component does not comprise a transistor, strain added to the front-side of the electronic component may also have a positive impact on the electrical performance of the package. In particular, a semiconductor material may be included in the electronic component which has the function of modulating the current flow. In particular a structure with such a semiconductor content may benefit from the proposed strain engineering concept.

In the following, further exemplary embodiments of the package and the method will be explained.

In the context of the present application, the term “package” may particularly denote an electronic device which may comprise one or more electronic components mounted on a carrier or with another front-side and/or back-side connection body. Said constituents of the package may be optionally encapsulated at least partially by an encapsulant. Further optionally, one or more electrically conductive interconnect bodies (such as bond wires) may be implemented in a package, for instance for electrically coupling the electronic component with the carrier and/or with leads.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), a light emitting, semiconductor-based device (such as a light emitting diode (LED) or LASER), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a naked die or may be already packaged or encapsulated. Semiconductor chips implemented according to exemplary embodiments may be formed in silicon technology, gallium nitride technology, silicon carbide technology, etc. Preferably, the at least one electronic component comprises a semiconductor chip, more specifically a metal oxide semiconductor field-effect transistor (MOSFET) chip.

In the context of the present application, the term “front-side connection body” may particularly denote a connection body made at least partially of an electrically conductive material such as a metal and being configured for attachment to the front-side of an electronic component. For example, such a front-side connection body may be a clip (such as a metallic plate structure), a carrier (such as a leadframe structure in a flip chip configuration of an electronic component), or a substrate-type carrier (like a direct copper bonding (DCB) substrate, a direct aluminum bonding (DAB) substrate or an active metal brazing (AMB) substrate).

In the context of the present application, the term “epitaxial layer” may denote a layer, a layer sequence or another structure at and/or in a surface region of a semiconductor body of an electronic component treated by semiconductor technology processing for forming at least one integrated circuit element at the epitaxial layer. In particular, the epitaxial layer may form or may form part of an active region of the electronic component. In the context of the present application, the term “active region” may particularly denote a surface region of a semiconductor substrate of an electronic component, in and/or on which surface region at least one monolithically integrated circuit element (such as a transistor, a diode, a capacitance, a resistor, etc.) is formed. In particular, such an active region may form a surface region of an electronic component at a front-side thereof. In a substrate-less chip the epitaxial structure may directly connected be to a back-side metallization.

In the context of the present application, the term “distance between epitaxial layer and front-side connection body” may particularly denote a spacing between epitaxial layer and front-side connection body. Said distance may be a constant distance, a minimum distance or an average distance between epitaxial layer and front-side connection body. Said distance between epitaxial layer and front-side connection body may be bridged by electrically conductive connection medium, such as a solder or a sinter material. Preferred may be a diffusion solder material being properly compatible with such small distances.

In an embodiment, a surface of the front-side connection body facing the electronic component is curved, in particular is curved in a convex fashion. For example, such an embodiment is shown in FIG. 3. However, it may also be curved in a concave fashion or with a complex arrangement of at least one concave and at least one convex section. Curving the connection surface of the front-side connection body may allow to bend the electronic component during assembly, which may add stress to the front-side of the electronic component and may therefore improve the electrical performance (in particular by reducing Rdson).

In an embodiment, the package comprises an electrically conductive connection medium connecting the electronic component with the front-side connection body, wherein in particular the connection medium is made of a material having a value of the Young modulus of at least 60 GPa at 20° C., more particularly of at least 100 GPa at 20° C. Thus, the connection between front-side connection body and front-side of the electronic component may be stiff or brittle for enhancing stress applied to the front-side of the electronic component. This may further improve the electrical performance (in particular by reducing Rdson).

In an embodiment, the front-side connection body is a clip. For example, such a clip may be a bent metallic plate structure. Such an embodiment is shown in FIG. 2 and FIG. 3. A clip may be a curved or three-dimensionally bent metal plate connecting electronic component with carrier and/or another electronic constituent of the package and/or of a periphery of the package. By clip assembly, front-side stress or strain may be applied or enhanced for improving the electrical performance.

In an embodiment, a lateral surface of the clip is structured for enhancing stress applied to the electronic component. Adjusting shape and/or dimension of the side surface of the clip is a further design parameter allowing for adjusting front-side stress exerted to the electronic component for reducing on-resistance.

In an embodiment, the front-side connection body is a carrier on which the electronic component is mounted, for example in a flip chip configuration. A corresponding embodiment is shown for example in FIG. 5.

In the context of the present application, the term “carrier” may particularly denote a support structure (which may be at least partially electrically conductive) which serves as a mechanical support for the one or more electronic components to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may comprise a die pad. In particular, a carrier may comprise at least a component assembly section and a lead section. However, the carrier may also be a substrate-type carrier (like a direct copper bonding (DCB) substrate, a direct aluminum bonding (DAB) substrate or an active metal brazing (AMB) substrate).

In the context of the present application, the term “flip chip configuration of an electronic component” may particularly denote that the electronic component is turned upside down so that its front-side (rather than its back-side) or active region is facing or contacting the carrier.

With a flip chip configuration of the electronic component with regard to a carrier, the carrier may act as a front-side connection body applying stress or strain to the front-side of the electronic component.

In another embodiment, the package comprises, in addition to the front-side connection body, a carrier (for example a leadframe structure or a metal layer-containing substrate structure), on which the electronic component is mounted. Such an embodiment is shown for instance in FIG. 6. It is for instance possible that a back-side of the electronic component is mounted on a bottom-sided carrier (such as a leadframe structure or a substrate) and that a top-sided front-side connection body (such as a substrate) is mounted on the front-side of the electronic component. For instance, the carrier can be a copper layer-containing substrate structure, such as a DCB or an AMB substrate. For example, an isolating ceramic substrate or a leadframe structure may be implemented. The carrier can also be any conductive carrier comprising copper as core material and may be plated with a layer which may comprise for example Ni, Ni, NiPd and/or Ag. The carrier can also comprise a ceramic core layer with copper (or aluminum) plated material on both sides of the ceramic core layer (such as a DAB substrate, a DCB substrate or an AMB substrate).

In an embodiment, a surface of the carrier facing a surface of the electronic component is curved, in particular is curved in a concave fashion. However, it may also be curved in a convex fashion or with a complex arrangement of at least one concave and at least one convex section. Curving the connection surface of the back-side carrier may allow to bend the electronic component during assembly, which may add stress to the back-side of the electronic component and may therefore improve the electrical performance (in particular by reducing Rdson).

In an embodiment, the package comprises a further electrically conductive connection medium connecting the electronic component with the carrier, wherein in particular a value of the Young modulus of the further electrically conductive connection medium is at least 60 GPa at 20° C., more particularly at least 100 GPa at 20° C. Thus, the connection between carrier and back-side of the electronic component may be stiff or brittle for enhancing stress applied to the back-side of the electronic component. This may further improve the electrical performance (in particular by reducing Rdson). In particular in combination with a stiff electrically conductive connection medium between front-side connection body and front-side of electronic component, a double-sided stress enhancement configuration may be obtained.

In an embodiment, the front-side connection body is an interposer, for example a structured interposer, or a substrate, for example comprising a ceramic. In particular, any kind of isolating substrate may be possible for the top side or front-side interconnect. For example, a ceramics material may be provided (directly or indirectly) as bottom side or back-side interconnect.

In an embodiment, the electronic component comprises a bulk layer and a metallization layer with the epitaxial layer in between, wherein the epitaxial layer is located closer to the front-side connection body than the bulk layer. For example, the bulk layer may be a semiconductor substrate, in particular a crystalline semiconductor substrate. For instance, the bulk layer may comprise or consist of silicon. The bulk layer may constitute the majority of the volume of the electronic component, for example more than 50% or at least 90% of the volume of the electronic component. The epitaxial layer may be formed in a surface portion of and/or on the bulk layer. The epitaxial layer covered by a front-side metallization may form the front-side of the electronic component, whereas the bulk layer covered by a back-side metallization may form the back-side of the electronic component. When exerting stress to both sides of the electronic component, a particularly pronounced improvement of the electric performance and reduction of the on-resistance may be achieved.

In an embodiment, thicknesses of the epitaxial layer, the metallization layer, a connection medium between the electronic component and the front-side connection body, and the front-side connection body have a relational link of 1: at least 2: at least 1: at least 20. With this ratio, excellent properties concerning Rdson may be obtained.

In an embodiment, the thickness of the epitaxial layer is in a range from 5 μm to 70 μm, in particular from 5 μm to 30 μm. In an embodiment, the thickness of the metallization layer is in a range from 1 μm to 20 μm, in particular from 2 μm to 10 μm. In an embodiment, the thickness of the connection medium is in a range from 0.5 μm to 50 μm, in particular from 1.5 μm to 10 μm, more particularly 2 μm to 5 μm. In particular, a range from 0.5 μm (for ultra-thin diffusion bonding) up to 50 μm (including some thicker solder or silver sinter layers) may be possible. More specifically, the range may be from 1.5 μm to 10 μm (covering a typical diffusion solder range). In an embodiment, the thickness of the front-side connection body is in a range from 100 μm to 3000 μm. In an embodiment, the thickness of the bulk layer of the electronic component may be smaller than the thickness of the front-side connection body but larger than any of the thicknesses of the epitaxial layer, the metallization layer and the connection medium.

In an embodiment, the distance between the epitaxial layer and the front-side connection body is less than 20 μm, in particular is less than 10 μm. In particular when a package with a high-voltage class of for example 1200 V is desired, a very small distance of less than 10 μm may be desired to meet the demanding requirements concerning electrical performance in this voltage class.

In an embodiment, the electronic component is at least one of a semiconductor chip (having a semiconductor bulk body), a transistor chip (in particular a field-effect transistor chip for which Rdson is an important performance parameter, such as a MOSFET or a JFET), a power chip (for which electronic performance is of utmost advantage), a vertical chip (experiencing a vertical current flow during operation), a silicon carbide chip (which is particularly advantageous for increasing stress or strain by a corresponding front-side configuration), a chip with super-junction (having an intrinsic configuration reducing additionally on-resistance), a unipolar chip, a bipolar chip, and a chip in flip-chip configuration (which can be mounted only on one side thereof while simultaneously achieving front-sided enhancement of strain or stress). Other configurations of the electronic component may however be possible.

In an embodiment, the connection medium and/or the further connection medium comprises a diffusion bonding material, for example AuSn, NiSn, CuSn and/or AgSn. Advantageously, diffusion bonding may be executed with a very low amount of solder material so that the thickness of a corresponding connection medium can be very small. Further advantageously, diffusion bonding or diffusion soldering may lead to a very stiff, rigid or brittle connection which may additionally enhance stress applied to the electronic component and preferably to the front-side thereof. Consequently, an excellent on-resistance behavior may be obtained.

In an embodiment, the connection medium and/or the further connection medium comprises a sinter material. Also a sinter material, for instance an Ag sinter paste, may be used for establishing the connection between front-side connection body and front-side of the electronic component and/or between the back-side of the electronic component and the carrier.

In an embodiment, the connection medium and/or the further connection medium has a thickness of not more than 20 μm, in particular not more than 10 μm, more particularly not more than 5 μm. This low thickness contribution of the connection medium may promote a small distance between the epitaxial layer and the front-side connection body, which may lead to an excellent electric performance of the package.

In an embodiment, the front-side connection body and the electronic component are designed so that stress applied to the electronic component is at least 200 MPa, in particular at least 700 MPa, more particularly at least 1500 MPa. Such a large stress or strain (in particular tensile strain or compressive strain), in particular when applied to the front-side of the electronic component, may result in a very low Rdson value.

In an embodiment, the front-side connection body, the electronic component, and an additional carrier on which a back-side of the electronic component is mounted are designed for applying stress to the electronic component at both opposing main surfaces thereof. Thus, a double-sided stress enhancement configuration may be obtained. This may lead, in turn, to excellent electrical properties of the package.

In an embodiment, the method comprises heating up the electronic component before and/or during said assembling and allowing the electronic component to cool down after said assembling. When the electronic component is heated up before and/or during assembly and reduced to a lower temperature after assembly, the electronic component can be frozen rigidly connected at the front-side connection body in a stressed condition by taking advantage of thermal stress created during said temperature cycle.

In an embodiment, the method comprises bending the electronic component by said assembling. Corresponding embodiments are shown in FIG. 3 and FIG. 5. Bending stress may be applied to the electronic component from a bottom-side and/or from a top-side, and in particular to the front-side of the electronic component where its active region or epitaxial layer is arranged. This may add a further stress contribution and may therefore reduce on-resistance.

In an embodiment, the method comprises enhancing stress exerted permanently to the electronic component by said assembling. Thus, the stress is not only applied during the manufacturing process but is conserved in the readily manufactured package. In other words, the assembled electronic component may remain under stress in particular at its front side (and optionally in addition also at its back-side) due to the various measures described herein. This may allow to maintain good electrical performance during long-term use of the package.

In an embodiment, the method comprises tuning a strain pattern of the electronic component to expose different areas of the electronic component to different strain levels to thereby tune an on-resistance characteristic of the electronic component. In particular, a defined two-dimensional strain or stress pattern may be applied to the electronic component onto its front-side, and optionally in addition also onto its back-side. By taking this measure, stress may be applied specifically to individual surface portions of the electronic component where the stress has a desired or pronounced impact on the package performance, in particular on the on-resistance of a field-effect transistor-type package.

For example, a desired stress pattern may be defined. Thereafter, measures may be defined for achieving the desired stress pattern (in particular adjusting the distance between the epitaxial layer and the front-side connection body, defining front-side and/or back-side connection medium with sufficient stiffness, adjusting a semiconductor type of an electronic component such as silicon carbide, adjusting an electronic component type such as super-junction type, etc.). Following common Co-Design procedures, a simulation may be carried out with the defined measure(s) and the simulation result may be compared with the desired stress pattern. Thereafter, the measure(s) may be adjusted to achieve better compliance with the desired stress pattern, as necessary. This procedure may be repeated iteratively a desired number of times. When a sufficient match has been achieved, the package may be manufactured correspondingly.

In an embodiment, the package comprises an encapsulant encapsulating at least part of the front-side connection body and at least part of the electronic component. In the context of the present application, the term “encapsulant” may particularly denote a substantially electrically insulating material surrounding at least part of electronic component and part of connection body to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity.

In an embodiment, the package is configured as power module, for instance molded power module such as a semiconductor power package. For instance, an exemplary embodiment of the package may be an intelligent power module (IPM). Another exemplary embodiment of the package is a dual inline package (DIP).

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, and a Thin Small Outline Package (TSOP) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts (in particular fully compatible with standard TO packaging concepts) and appears externally as a conventional package, which is highly user convenient.

In an embodiment, the electronic component is a semiconductor power chip. Thus, the semiconductor component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). In particular, exemplary embodiments may be implemented advantageously for an electronic component with vertical current flow. Strain engineering according to exemplary embodiments may be particularly beneficial when a current flow is vertical and is running through a relatively-doped epitaxial layer. In such a scenario, the advantageous properties of exemplary embodiments are particularly pronounced. A semiconductor power chip may comprise one or more field effect transistors, diodes, inverter circuits, half-bridges, full-bridges, drivers, logic circuits, further devices, etc.

In an embodiment, the package comprises a plurality of electronic components, in particular semiconductor components, preferably encapsulated by an encapsulant. Thus, the package may comprise one or more semiconductor components (for instance at least one passive component, such as a capacitor, and at least one active component).

As substrate or wafer forming the basis of the electronic component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of part of a package according to an exemplary embodiment.

FIG. 2 illustrates a cross-sectional view of a package according to an exemplary embodiment.

FIG. 3 illustrates a cross-sectional view of a package according to another exemplary embodiment.

FIG. 4 illustrates a plan view of a package according to an exemplary embodiment and simulation results.

FIG. 5 illustrates a cross-sectional view of a package according to another exemplary embodiment.

FIG. 6 illustrates a cross-sectional view of a package according to another exemplary embodiment.

FIG. 7 to FIG. 10 show cross-sectional views of structures obtained during carrying out a method of manufacturing a package, shown in FIGS. 10, according to an exemplary embodiment.

FIG. 11 illustrates a diagram illustrating simulation results of a package according to an exemplary embodiment.

FIG. 12 illustrates a diagram illustrating simulation results of a package according to an exemplary embodiment.

FIG. 13 illustrates structures illustrating simulation results of a package according to an exemplary embodiment.

FIG. 14 illustrates structures illustrating simulation results of a package according to an exemplary embodiment.

FIG. 15 illustrates a cross-sectional view of part of a package according to an exemplary embodiment.

FIG. 16 illustrates a diagram illustrating simulation results of a package according to an exemplary embodiment.

FIG. 17 illustrates a cross-sectional view of an electronic component of a package according to an exemplary embodiment.

### DETAILED DESCRIPTION

The illustration in the drawing is schematically and not to scale.

Before exemplary embodiments will be described in more detail referring to the figures, some general considerations will be summarized based on which exemplary embodiments have been developed.

Rdson is a key figure of merit for MOSFET-type electronic components. To reduce the on-resistance of vertical power devices, the following technologies can be considered: super-junction architectures (relating to front-end technology) and strain engineering (realizable through front-end and back-end technology).

However, especially for silicon carbide-type electronic components, super-junction architectures alone may not be impactful enough to meet demanding on-resistance targets. Even if such constructions (i.e. super-junction architectures) meet the on-resistance targets, manufacturing effort of such devices may be very high.

Packages formed on the basis of silicon carbide MOSFETS implementing back-end interconnect technologies may be able to improve Rdson behavior to a certain degree. Thus, leveraging strain engineering may improve on-resistances in power packages. Introducing strain into the chip structure by means of back-end interconnect technologies can have a profound effect on Rdson.

However, back-side interconnects are considered as the only back-end method to leverage strain engineering effects for Rdson improvements. Common front-side interconnects are to date still dominated by wire-bonded technologies without potential of introducing a significant amount of stress into the chip. If other front side interconnect technologies (in particular clips) are deployed, strain engineering effects to reduce Rdson are challenging to leverage, as the interconnect (most often Pb-solder based) has a small Young modulus thereby restraining the application of meaningful mechanical stress levels into the chip.

According to an exemplary embodiment, a package comprising one or more electronic components (in particular semiconductor power chips) may be provided with advantageous electric performance in particular in terms of drain-source on resistance. In such a package, an electrically conductive front-side connection body (like a clip) may be implemented for forming an electrically conductive connection at the front-side or with the active region of the one or more electronic components. The epitaxial layer or active region of the at least one electronic component may face the front-side connection body and may be connected with the connection body, for example by diffusion soldering. Beneficially, a distance (which may be a minimum distance, a constant distance or an average distance) between the epitaxial layer and the front-side connection body may have an extraordinarily small value of less than 50 μm. Advantageously, such a small spacing of the active region with respect to the front-sided connection body may exert an amount of strain at the front-side of the electronic component which may significantly decrease the drain-source on-resistance of the at least one electronic component and the package as a whole. As a result, the package may have a small Rdson value, which may have a positive impact on maximum current rating and current loss. To put it shortly, an exemplary embodiment provides a strain-inducing front side assembly.

Without wishing to be bound to a specific theory, it is presently believed that compressive stress applied in parallel to the substrate plane may provide a particularly pronounced improvement of Rdson for currents flowing perpendicular to the applied mechanical stress. Among other reasons, it is presently believed that a lowering of the band edge, realized by a compressive, mechanical stress environment, may allow a more complete trap state incorporation into the conduction band thereby allowing a less trap-assisted current flow through the semiconductor lattice.

To leverage crystal straining effects for on-resistance gain as efficient as possible, it may be advantageous to place the stressing element as close as possible to the (in particular low doped) epitaxial layer of the electronic component. Advantageously, a package interconnect technology may be implemented applying the stress from relatively close to the electronic component's epitaxial layer, i.e. preferably less than 50 μm. Beneficially, the package interconnect may be accomplished by diffusion soldering (in particular an AuSn diffusion bonded interconnect) rather than soft soldering. Beneficially, strain engineering may be applied in particular to silicon carbide devices, preferably through a bent clip architecture. To put it shortly, it may be possible to tune strain in the active area of the electronic component through package interconnect parameters which impact Rdson without changing the basic package type or the package footprint. Further advantageously, exemplary embodiments may increase flexibility to reach a proper or even the best in class performance at a given package footprint.

Contrary to conventional approaches, the potential of a further increase in chip stress by correspondingly designing front-side interconnects has been considered by the present inventors. For instance, this may be achieved by assembling a clip-type front-side connection body by a hard interface.

Exemplary embodiments may implement one or more of the following elements for improving the electric performance by adding strain or stress: Advantageously, a structured clip architecture may be applied presenting a non-flat surface to the chip front-side metallization. Beneficially, a coined or bent clip and/or a structured interposer may be connected to the front-side of the electronic component. Also a lateral structuring of a clip to tune a strain pattern on the electronic component may be advantageous. Further beneficially, an interconnection between front-sided connection body and electronic component may be accomplished by a connection medium having a high Young modulus value, which may advantageously lead to a stiff interconnect adding stress to the electronic component. Preferably, the front-sided connection body may be connected with the electronic component by diffusion bonding (for instance using AuSn or NiSn as diffusion bonding connection medium), sintering, etc. A further preferred option may be a hot die attach (for instance on a bent leadframe) resulting in a mechanically definable, constraint chip environment. A benefit of applying stress from both sides is that the chip has less options left to relax the imposed mechanical stress by chip shape deformation. Exemplary embodiments may add compressive mechanical stress parallel to the substrate plane in the active chip area thanks to the corresponding formation of a connection between front-side connection body and the epitaxial layer of the electronic component with a mutual vertical spacing of less than 50 μm. By taking one, some or all of the aforementioned measures, an improvement of chip Rdson may be achieved by stress introduction through the front-side of the electronic component.

In particular, it may be possible to tune the strain pattern applied to the electronic component by clip shape variation or adaptation. In particular, stress uptake may modulate the bandgap of a semiconductor material of the electronic component, in particular pronounced and advantageous for a silicon carbide-based electronic component. For Silicon-carbide preferably, the connection between the epitaxial layer of the electronic component and the front-side connection body may be configured so that stress uptake occurs perpendicular to the crystals c-plane. This has turned out to lead to a particular efficient bandgap modulation.

Without wishing to be bound to a specific theory, it is presently believed that a large quantity of interfacial states (e.g. located at the SiC-poly interface) are located energetically approximately 0.2 eV lower than the conduction band. A small bandgap lowering by stress uptake may incorporate states into the conduction band. This may reduce the portion of performance detrimental trap-mediated transport during current conduction. Furthermore, it is presently believed that compressive stress along the crystals c-plane may be particularly well-suited for Rdson improvement in devices relying on a vertical current flow. Such compressive stress may allow a larger proportion of trap states being incorporated into the conduction band thereby reducing Ron.

In an embodiment, strain engineering at the front-side of an electronic component may be used to reduce Rdson, in particular for SiC-type MOSFETs. In yet another embodiment, added front-sided stress thanks to a spatially close connection of front-side connection body with an epitaxial layer of the electronic component may be synergistically combined with carrier compensation concepts such as a super-junction architecture of the electronic component. Additionally or alternatively, added front-sided stress thanks to a spatially close connection of front-side connection body with an epitaxial layer of the electronic component may be synergistically combined with added back-sided stress to reduce or even minimize potential stress relaxation through chip deformation, for instance by a rigid or stiff connection between a leadframe structure-type carrier with the back-side of the electronic component.

In particular, a small or even minimized distance of a (for example multi-laterally, horizontally acting) mechanical stressor element to an epitaxial layer may be highly advantageous to improve Rdson. For instance for SiC MOSFETs, it is presently believed that a 700 MPa multi-lateral, compressive stress applied to an epitaxial layer with a distance of 10 μm may lead to about 3.5% gain in terms of Rdson.

Exemplary embodiments may realize this by a clip with stiff clip attach and/or a flip chip configuration with stiff die attach. A preferred embodiment may relate to a silicon-based device (for instance comprising silicon carbide) structured in an epitaxial layer, a bulk layer and at least one metallization layer and which is interconnected to an electrically conductive carrier substrate (such as a clip or a substrate via a flip chip configuration) using a connecting layer (for example a diffusion bond layer). Advantageously, the epitaxial layer may be located spatially close to the electrically conductive carrier (such as the clip or the flip chip substrate). Advantageously, highly appropriate thicknesses of the involved structural elements may be as follows: epitaxial layer (5 μm to 30 μm); closest metallization layer (5 μm to 20 μm); connecting layer (2 μm to 5 μm); the electrically conductive carrier substrate (200 μm to 3000 μm); the mentioned structural elements (in the described order) may have a relational link of 1: at least 2 (or smaller): at least 1 (or smaller): 20 (or larger).

Preferably, a connecting layer or a connection medium may comprise brittle solder material, preferably diffusion solder materials, more preferably diffusion solderable materials comprising AuSn, NiSn, CuSn or AgSn. Highly advantageously, the distance between the epitaxial layer and the carrier substrate may be less than 10 μm.

In a preferred embodiment, an areal compressive stress in the epitaxial layer parallel to the chip surface may be more than 200 MPa, preferably 700 MPa or more, most preferably 1500 MPa or more.

The semiconductor chip may be a power semiconductor chip, preferably a vertical power semiconductor chip.

The areal compressive stress in the epitaxial layer parallel to the chip surface before mounting the semiconductor chip on the electrically conducting substrate may be lower than after mounting.

In embodiments, the manufacturing method may be applicable for unipolar or bipolar power chip technologies which may optionally also comprise internal power chip structures such as super-junction architectures.

A strong indication for an improvement of the Rdson behavior has been provided by ANSIS strain simulation and DFT (Density Functional Theory) calculation.

Exemplary applications of exemplary embodiments are high power-applications, for instance in the industrial and automotive fields.

Advantageously, packages with improved Rdson behavior may reduce manufacturing effort and may lead to chip-shrinkage. Furthermore, chip and/or device performance may be improved. Cooling requirements may be relaxed.

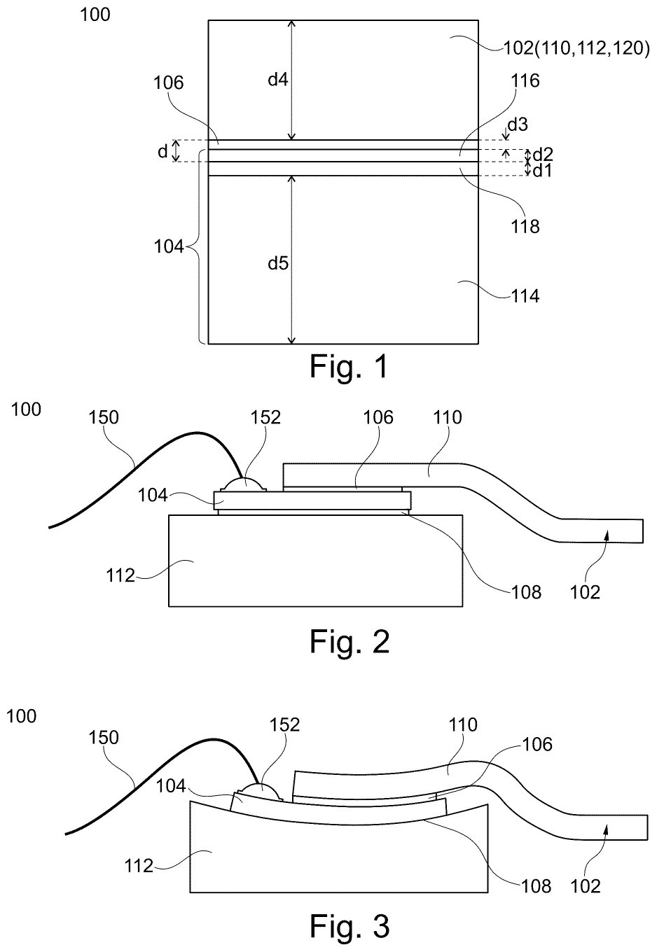

FIG. 1 illustrates a cross-sectional view of part of a package 100 according to an exemplary embodiment.

The shown portion of power package 100 illustrates an interface region between a metallic front-side connection body 102 and a semiconductor-type electronic component 104. For example, front-side connection body 102 can be embodied as a clip (see reference sign 110 in FIG. 2), as a leadframe structure-type carrier (see reference sign 112 in FIG. 5) or as a substrate with a central electrically insulating and thermally conductive sheet covered on both opposing main surfaces thereof by a respective metallic layer (see reference sign 120 in FIG. 6). For example, the electronic component 104 can be a semiconductor die. The front-side of the electronic component 104 may be connected with the front-side connection body 102 by a layer of an electrically conductive connection medium (see reference sign 106 in FIG. 2, 3, 5 or 6)

More specifically, the electronic component 104 may have an epitaxial layer 118 on top of a semiconductor bulk layer 114. The epitaxial layer 118 may correspond to an active region of the semiconductor die-type electronic component 104 and may comprise at least one monolithically integrated circuit element, in particular a monolithically integrated field-effect transistor. On top of the epitaxial layer 118, a metallization layer 116 may be formed. The metallization layer 116 may comprise a sequence of stacked metallic sub-layers. Thus, the electronic component 104 comprises bulk layer 114 and metallization layer 116 with the epitaxial layer 118 in between, so that the epitaxial layer 118 is located closer to the front-side connection body 102 than the bulk layer 114. In other words, a front-side of the electronic component 104 may be connected to the front-side connection body 102 by the connection medium 106 in between. The metallization layer 116 of the electronic component 104 may be connected with the front-side connection body 102 by a layer of the electrically conductive connection medium 106 in between. Preferably, the electrically conductive connection medium 106 may be a layer or a thin-film of diffusion solder.

Advantageously, a vertical distance d between the epitaxial layer 118 and the front-side connection body 102 is less than 50 μm, preferably less than 20 μm, and more preferably less than 10 μm. Advantageously, such a small vertical distance d between the epitaxial layer 118 and the front-side connection body 102 may add a considerable amount of stress or strain to the front-side of the electronic component 102 very close to its active region which may improve the electrical performance of the package 100 thanks to a reduction of Rdson resulting from d<50 μm. Said vertical distance d is composed of a thickness d2 of the metallization layer 116 and a thickness d3 of the layer of connection medium 106. A thickness of the epitaxial layer 118 is denoted as d1. As can be taken from FIG. 1 as well, a vertical thickness d4 of the front-side connection body 102 as well as a thickness d5 of the bulk body 114 of the electronic component 104 may be significantly larger than each of d1, d2 and d3.

For instance, the thickness d1 of the epitaxial layer 118 may be in a range from 5 μm to 30 μm, in particular from 10 μm to 20 μm. For example, the thickness d2 of the metallization layer 116 may be in a range from 5 μm to 20 μm, in particular from 8 μm to 15 μm. In embodiments, the thickness d3 of the connection medium 106 may be in a range from 2 μm to 5 μm, in particular from 2.5 μm to 4.5 μm. For instance, the thickness d4 of the front-side connection body 102 may be in a range from 200 μm to 3000 μm, in particular in a range from 500 μm to 1000 μm. For instance, the thickness d5 of the bulk layer 114 may be in a range from 30 μm to 500 μm, in particular in a range from 50 μm to 200 μm. Preferably, the thicknesses d1, d2, d3, d4 of the epitaxial layer 118, the metallization layer 116, the connection medium 106, and the front-side connection body 102 may have a relational link of 1: at least 2: at least 1: at least 20.

Now referring in further detail to the electrically conductive connection medium 106 connecting the electronic component 104 with the front-side connection body 102, said connection medium 106 may be made of a material having a value of the Young modulus of at least 60 GPa at 20° C. or even of at least 100 GPa at 20° C. Descriptively speaking, this may lead to a stiff rather than soft connection between electronic component 104 and front-side connection body 102 adding a significant amount of stress or strain to the front-side of the electronic component 104 in a defined way.

FIG. 2 illustrates a cross-sectional view of a package 100 according to an exemplary embodiment. Package 100 according to FIG. 2 may have a configuration as illustrated and described referring to FIG. 1. The illustrated package 100 may be a power package.

Package 100 comprises a bottom-sided carrier 112, for example a patterned metal plate or leadframe structure made of a metallic material such as copper or aluminum, on which a back-side of the electronic component 104 is mounted by electrically conductive connection medium 108.

Advantageously, a value of the Young modulus of the electrically conductive connection medium 108 may be at least 60 GPa at 20° C. or even at least 100 GPa at 20° C. By providing such a stiff connection between carrier 112 and the back-side of the electronic component 104, stress or strain may be exerted to the back-side of the electronic component 104 which may have a positive impact on the electrical performance, more specifically may reduce Rdson. For example, the connection medium 108 comprises a diffusion bonding material, for example AuSn, NiSn, CuSn and/or AgSn. Preferably, the connection medium 108 has a thickness of not more than 10 μm or even not more than 5 μm.

Package 100 may comprise metallic front-side connection body 102 which is here embodied as a clip 110. Said clip 110 may be a bent metal plate, for instance made of copper. Electronic component 104, which may be a semiconductor die for instance manufactured in silicon carbide technology, may have an epitaxial layer 118 or active region which may be assembled with the front-side connection body 102 with a distance d between the epitaxial layer 118 and the front-side connection body 102 being less than 50 μm, preferably being less than 20 μm or even less than 10 μm (see FIG. 1). Assembly of the front-side connection body 102 through the front-side of the electronic component 104 may be via a connection medium 106 which may be a thin-film of diffusion solder.

Advantageously, a value of the Young modulus of the electrically conductive connection medium 106 may be at least 60 GPa at 20° C. or even at least 100 GPa at 20° C. By providing such a stiff connection between clip 110 and the front-side of the electronic component 104, stress or strain may be exerted to the front-side of the electronic component 104 which may have a very pronounced positive impact on the electrical performance, more specifically may reduce Rdson. For example, the connection medium 106 comprises a diffusion bonding material, for example AuSn, NiSn, CuSn and/or AgSn. Preferably, the connection medium 106 has a thickness d3 of not more than 10 μm or even not more than 5 μm.

It may be advantageous that, thanks to the described and illustrated configuration, the front-side connection body 102 and the electronic component 104 apply stress to the electronic component 104 of at least 200 MPa and preferably at least 1500 MPa. Thanks to the described configuration, the front-side connection body 102, the electronic component 104, the additional carrier 112 on which a back-side of the electronic component 104 is mounted, as well as the connection media 106, 108 are designed for applying stress to the electronic component 104 at both opposing main surfaces thereof. By configuring the electronic component 104 as a super-junction chip (compare FIG. 17), the electronic performance and in particular the Rdson behavior may be further improved. By the described configuration of FIG. 2, double-sided stressing may be achieved.

According to FIG. 2, a surface of the front-side connection body 102 facing the electronic component 104 is flat or planar. Correspondingly, a surface of the carrier 112 facing a surface of the electronic component 104 is flat or planar.

As shown as well in FIG. 2, a terminal (for instance a gate terminal) of the electronic component 104 may be connected by a metallic bond wire 152 to an electronic periphery (for instance to a lead structure, not shown in FIG. 2, to the carrier 112 and/or to another element). The bond wire 150 may be connected to the terminal of the electronic component 104 by a bonding structure 152, such as a solder bump.

FIG. 3 illustrates a cross-sectional view of a package 100 according to another exemplary embodiment. Package 100 according to FIG. 3 may have a configuration as illustrated and described referring to FIG. 1.

The embodiment of FIG. 3 differs from the embodiment according to FIG. 2 in particular in that, according to FIG. 3, a surface of the front-side connection body 102 facing the electronic component 104 is curved in a convex fashion. Correspondingly, a surface of the carrier 112 facing a surface of the electronic component 104 is curved in a concave fashion. Thus, FIG. 3 shows an embodiment with a clip 110 which presents a curved, non-flat surface area (which may be realized for example by coining or bending) to the chip front side, which, in conjunction with an oppositely curved mounting surface of carrier 112, introduces lattice strain into the electronic component 104 to tune the on-resistance, such as the Rdson behavior.

By connecting the electronic component 104 with the carrier 112 and the clip 110 by sintering or diffusion soldering, the curvature may be fixed during the process. In particular when the electronic component 104 is manufactured in silicon carbide technology, bending may be applied into defined crystal directions leading to a pronounced increase of stress or strain.

Other bending structures of carrier 112 and/or clip 110, for example more complicated structures, can be realized in order to expose different chip areas to different stress or strain levels.

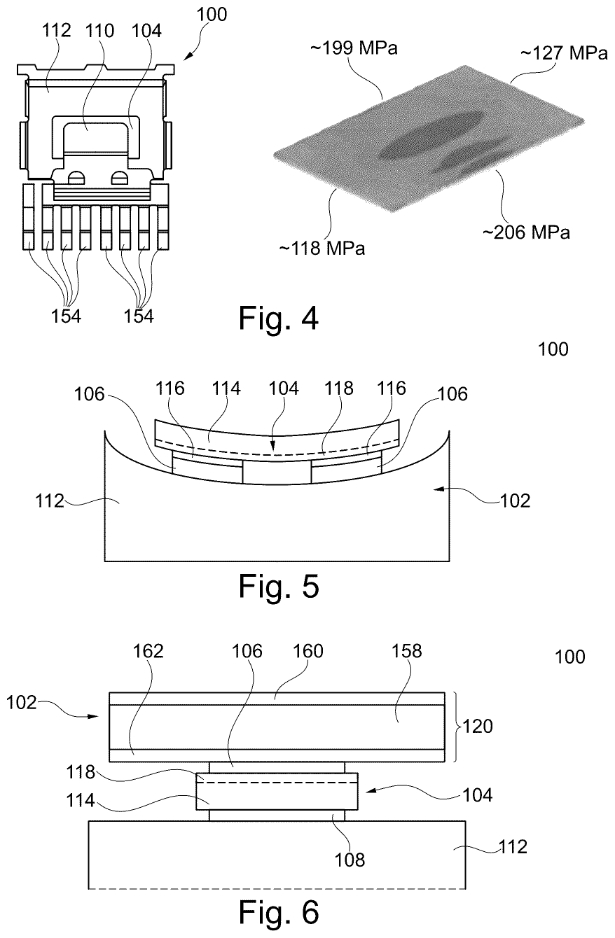

FIG. 4 illustrates a plan view of a package 100 (left-hand side) according to an exemplary embodiment and simulation results (right-hand side).

FIG. 4 illustrates on the left-hand side that the clip 110 may be electrically coupled with leads 154 of the package 100.

The simulation results on the right-hand side indicate that a significant amount of stress or strain can be applied to the electronic component 104 thanks to the packaging architecture described herein.

FIG. 5 illustrates a cross-sectional view of a package 100 according to another exemplary embodiment. Package 100 according to FIG. 5 may have a configuration as illustrated and described referring to FIG. 1.

The embodiment of FIG. 5 differs from the embodiment according to FIG. 2 in particular in that, according to FIG. 5, the front-side connection body 102 is a carrier 112 on which the electronic component 104 is mounted in a flip chip configuration. For instance, carrier 112 may be curved at its connection surface (or may be flat, not shown). The electronic component 104 arranged in flip chip configuration may have its epitaxial layer 118 or active region arranged to face the carrier 112. In another embodiment with the chip architecture according to FIG. 5, the front-side connection body 102 may have a planar connection surface (not shown).

FIG. 6 illustrates a cross-sectional view of a package 100 according to another exemplary embodiment. Package 100 according to FIG. 6 may have a configuration as illustrated and described referring to FIG. 1.

The embodiment of FIG. 6 differs from the embodiment according to FIG. 2 in particular in that, according to FIG. 6, clip 110 is substituted by a substrate 120 as front-side connection body 102. More specifically, package 100 according to FIG. 6 comprises a bottom-sided carrier 112, for example a leadframe structure, on which the electronic component 104 is mounted. Moreover, front-side connection body 102 is embodied as substrate 120 comprising a ceramic and being assembled to the front-side of the electronic component 104 by connection medium 106. In the configuration of FIG. 6, the epitaxial layer 118 faces the substrate 120 rather than the carrier 112.

Still referring to FIG. 6, substrate 120 is here embodied as an electrically insulating and thermally conductive sheet 158 covered on both opposing main surfaces thereof with a respective metallic layer 160, 162 (which may be continuous or patterned), respectively. For example, electrically insulating and thermally conductive sheet 158 may be made of a ceramic. For instance, each of metallic layers 160, 162 may be a copper foil. For instance, substrate 120 may be a DCB substrate, a DAB substrate or an AMB substrate.

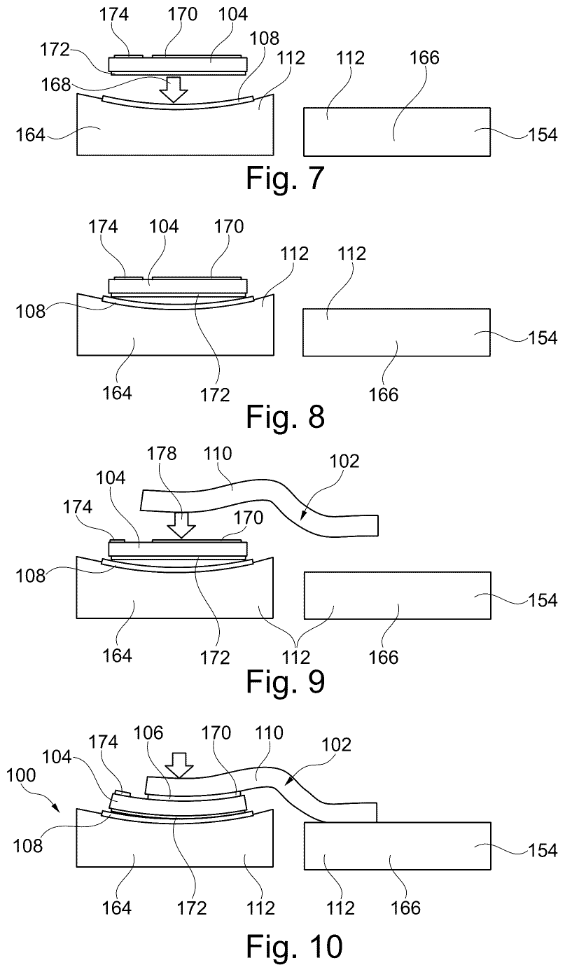

FIG. 7 to FIG. 10 show cross-sectional views of structures obtained during carrying out a method of manufacturing a package 100, shown in FIGS. 10, according to an exemplary embodiment.

Referring to FIG. 7, back-side carrier 112 is provided with a curved mounting surface for receiving electronic component 104 thereon. For instance, back-side carrier 112 may comprise a die pad 164 for accommodating electronic component 104 and a separate lead structure 166 comprising one or a plurality of leads 154. Connection medium 108 may be formed on a connection surface of carrier 112 for receiving a back-side of electronic component 104. For instance, connection medium 108 may be a thin-film of diffusion solder.

By an arrow 168, FIG. 7 illustrates die placement onto the die pad 164 (carrier 112 may be for example a leadframe or another substrate) with required geometry.

In the shown configuration, electronic component 104 is a field-effect transistor chip having a source terminal 170, a drain terminal 172 and a gate terminal 174. Drain terminal 172 is arranged on a bottom main surface of the electronic component 104 and may be connected to die pad 164. The source terminal 170 and the gate terminal 174 are arranged side-by-side on the top main surface of the electronic component 104. Electronic component 104 experiences a vertical current flow during operation.

Referring to FIG. 8, electronic component 104 has reached the mounting surface of the carrier 112.

Referring to FIG. 9, a clip 112 with a curved connection surface towards electronic component 104 is provided as front-side connection body 102 and is attached to the source pad 170 of the electronic component 104, see arrow 178. In other words, FIG. 9 shows placement of the clip 110 onto the die-type electronic component 104. Advantageously, the clip geometry (in particular its curvature) of clip 110 fits to the carrier geometry (in particular its curvature) of carrier 112, in particular a leadframe structure.

Referring to FIG. 10, the electrically conductive front-side connection body 102 is assembled with the front-side of the electronic component 104 at its epitaxial layer 118. More specifically, the front-side connection body 102 is arranged with respect to the electronic component 104 so that distance d (see FIG. 1) between the epitaxial layer 118 and the front-side connection body 102 is less than 50 μm. Optionally but advantageously, it may be possible to heat up the electronic component 104 before and/or during said assembling, and the electronic component 104 may be allowed to cool down (for instance by active cooling or passively) after said assembling. Due to the matching curved geometry of carrier 112 and clip 110, it may be possible to bend the electronic component 104 by said assembling (see FIG. 10), thereby applying additional strain or stress. Consequently, chip bending may be enforced during formation of die attach and clip attach (preferably by diffusion soldering or sintering). The enhanced stress applied during the illustrated assembly process may be exerted permanently to the electronic component 104, i.e. also after said assembling. Added stress components may result from stiff front-side connection by connection medium 106, short-distance (d) connection between epitaxial layer 118 and front-side connection body 102, stiff back-side connection by connection medium 108, curvature of carrier 112 and/or clip 110, configuration of electronic component 104 as silicon carbide die and/or super-junction die. By correspondingly adjusting the aforementioned phenomena by a selection of constituents of package 100 and/or the manufacturing method, it may be possible to tune the two-dimensional strain pattern of the electronic component 104 on its upper side and/or on its bottom side to expose different areas of the electronic component 104 to different strain levels. This may allow to selectively tune an on-resistance characteristic of the electronic component 104.

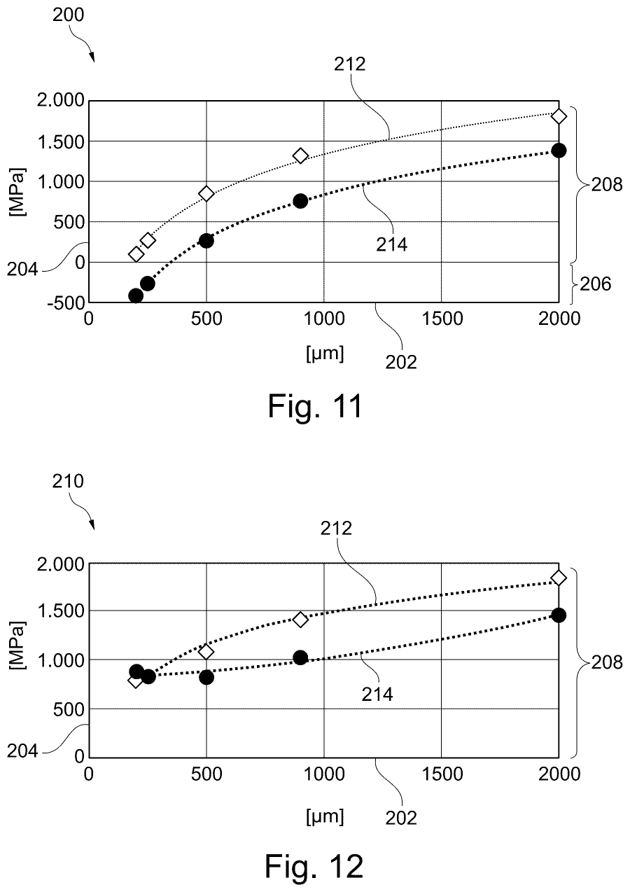

FIG. 11 illustrates a diagram 200 illustrating simulation results of a package 100 according to an exemplary embodiment. Diagram 200 has an abscissa 202 along which a copper leadframe thickness is plotted in micrometres. Along an ordinate 204 of diagram 200, stress in parallel to the SiC crystals c-plane (in MPa) is plotted. A region of tensile stress is indicated by reference sign 206, whereas a region of compressive stress is indicated by reference sign 208. A curve 212 relates to a 55 μm silicon carbide chip, whereas a curve 214 relates to a 110 μm silicon carbide chip. The simulation results according to FIG. 11 relate to a top side of the chip. FIG. 12 illustrates a diagram 210 illustrating simulation results of a package 100 according to an exemplary embodiment. The simulation results according to FIG. 12 relate to a bottom side of the chip.

The simulation according to FIG. 11 and FIG. 12 has been carried out based on an unstructured chip. A simplified bi-material beam approximation additionally including an AuSn interlayer between the Cu leadframe and the unstructured SiC Chip has been made. The model has been checked with a CoolMOS simulation.

The simulation of FIG. 11 and FIG. 12 shows that in particular compressive stress can be introduced into a silicon carbide chip by means of package interconnect engineering.

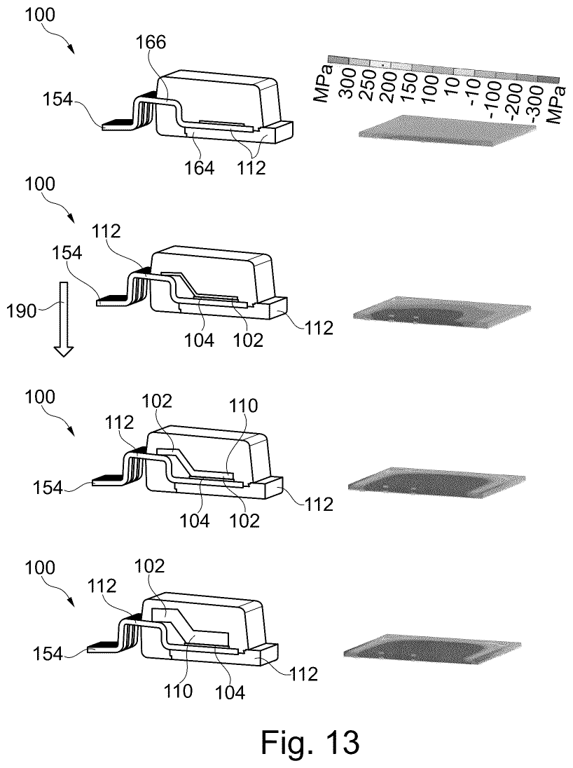

FIG. 13 illustrates structures illustrating simulation results of a package 100 according to an exemplary embodiment. More specifically, the left-hand side of FIG. 13 shows cross-sectional views of designs of packages 100 with varying clip thicknesses. An arrow 190 indicates a direction of increasing clip thicknesses. On the right-hand side of FIG. 13, the result of strain simulations is shown. FIG. 13 relates to a leadframe thickness of 1.27 mm.

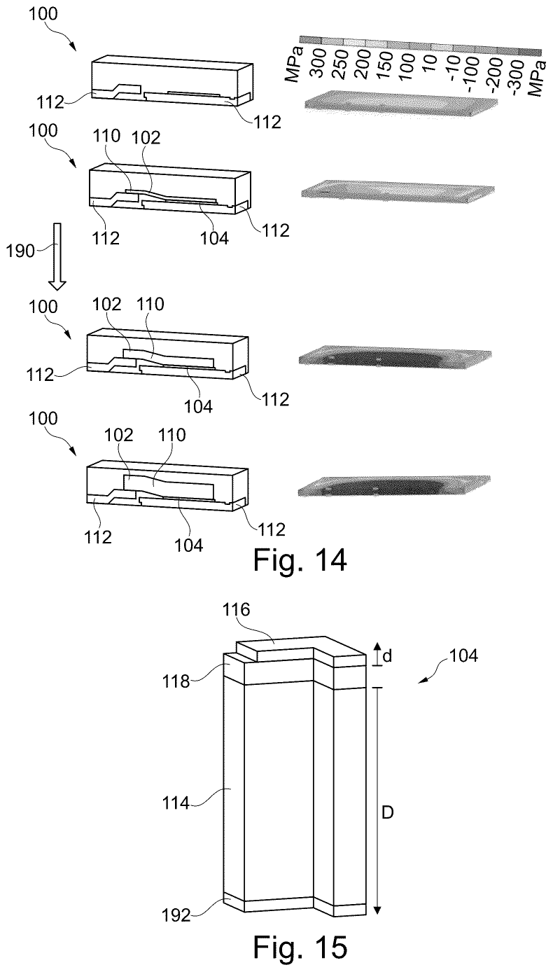

FIG. 14 illustrates structures illustrating simulation results of a package 100 according to an exemplary embodiment. FIG. 14 shows corresponding simulation results as FIG. 13, however for another package-type (in particular with different leadframe thickness). FIG. 14 relates to a leadframe thickness of 0.5 mm.

Descriptively speaking, FIG. 13 and FIG. 14 relate to simulation results for figuring out which stress can be applied by tuning clip thickness and carrier thickness. As shown in FIG. 13 and FIG. 14, stress applied to epitaxial layer 118 of electronic component 104 has a very pronounced impact on strain. In particular with a relatively safe split 110 and a relatively safe carrier 100 stress, a significant reduction of Rdson can be achieved, for instance 6 to 7%.

FIG. 15 illustrates a cross-sectional view of part of a package 100 according to an exemplary embodiment.

More specifically, FIG. 15 illustrates a common stack configuration of constituents of an electronic component 104. On the top side, a metallization layer 116 is arranged on top of an epitaxial layer 118 being arranged, in turn, on semiconductor bulk body 114. On the bottom side, a back-end metallization 192 is shown as a substrate layer.

On the one hand, distance d from the epitaxial layer 118 to the front-side connection body 102 is preferably less than 10 μm. On the other hand, distance D from the epitaxial layer 118 to the back-side interconnection can be more than 100 μm (preferably for a voltage class of 1200 V). The voltage the chip can maximally block is mainly defined by the thickness of the epitaxial layer 118. Thickness D may range for example between 250 μm and 20 μm.

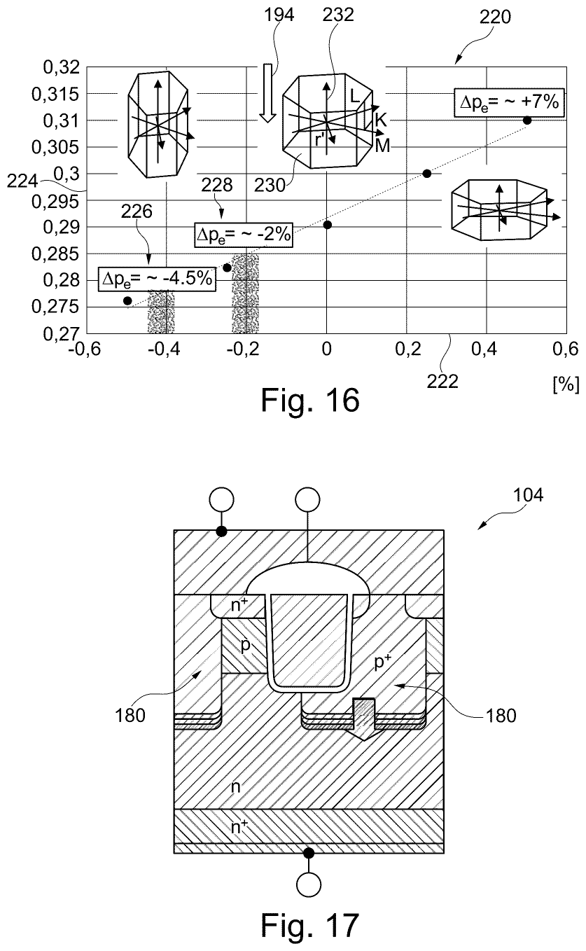

FIG. 16 illustrates a diagram 220 illustrating simulation results of a package 100 according to an exemplary embodiment. Diagram 220 has an abscissa 222 along which biaxial strain within a crystal c-plane (see reference sign 230) is plotted in percent. Along an ordinate 224 of diagram 220, an effective carrier mass along the crystal c-axis (see reference sign 232) is plotted. An arrow 194 indicates a current direction. A data element 226 relates to a 1.27 mm leadframe, whereas a data element 228 relates to a 500 μm leadframe. The simulation evaluates the relative impact of biaxial mechanical stress of the c-plane on the effective carrier mass perpendicular to the stressor plane (indicated by the arrow 194) in a perfect SiC unit cell. In a first approximation (neglecting common scattering phenomena) the simulated carrier mass can be considered directly proportional to the resistance through the SiC unit cell in arrow direction.

The put it shortly, diagram 220 indicates a significant drop of on-resistance by the addition of front-side stress.

FIG. 17 illustrates a cross-sectional view of an electronic component 104 of a package 100 according to an exemplary embodiment.

The illustrated electronic component 104 is configured in a super-junction architecture which is known, as such, by a person skilled in the art. However, a similar trench structure may be advantageously implemented in a package 100 according to an exemplary embodiment to further increase the strain or stress applied to the electronic component 104, in addition to one or more of the corresponding measures explained herein.

In particular, such a super-junction type electronic component 104 may integrate charge-balancing, deep P-doped columns 180 in the active region of the electronic component 104. A super-junction structure may be used for charge balancing, in particular using differently doped material of the same kind.

In particular, a combination of front-end super-junction and front-end and/or back-end strain engineering technologies may lead to lower Rdson. Preferably, super-junction architectures may be implemented in SiC MOSFETs. Care should be taken concerning channeling and implant process stability. In particular, it may be advantageous to apply a partial super-junction for reducing manufacturing effort in combination with front-end strain engineering.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a front-side connection body that is at least partially electrically conductive; and
an electronic component having an epitaxial layer and being assembled with the front-side connection body;
wherein a distance between the epitaxial layer and the front-side connection body is less than 50 μm.

2. The package of claim 1, wherein a surface of the front-side connection body facing the electronic component is curved in a convex fashion.

3. The package of claim 1, further comprising:
an electrically conductive connection medium connecting the electronic component with the front-side connection body,
wherein the connection medium is made of a material having a Young modulus value of at least 60 GPa at 20° C.

4. The package of claim 3, wherein at least one of:
the connection medium comprises a diffusion bonding material;
the connection medium comprises a sinter material; and
the connection medium has a thickness of not more than 20 μm.

5. The package of claim 1, wherein the front-side connection body is a clip.

6. The package of claim 5, wherein a lateral surface of the clip is structured to enhance stress applied to the electronic component.

7. The package of claim 1, wherein the front-side connection body is a carrier on which the electronic component is mounted.

8. The package of claim 7, wherein a surface of the carrier facing a surface of the electronic component is curved in a concave fashion.

9. The package of claim 1, further comprising:
a carrier on which the electronic component is mounted.

10. The package of claim 9, wherein a surface of the carrier facing a surface of the electronic component is curved in a concave fashion.

11. The package of claim 9, further comprising:
a further electrically conductive connection medium connecting the electronic component with the carrier,
wherein a Young modulus value of the further electrically conductive connection medium is at least 60 GPa at 20° C.

12. The package of claim 1, wherein the front-side connection body is an interposer.

13. The package of claim 1, wherein the electronic component comprises a bulk layer and a metallization layer with the epitaxial layer in between, and wherein the epitaxial layer is located closer to the front-side connection body than the bulk layer.

14. The package of claim 13, wherein thicknesses of the epitaxial layer, the metallization layer, a connection medium between the electronic component and the front-side connection body, and the front-side connection body have a relational link of 1 to at least 2.

15. The package of claim 14, wherein at least one of:
the thickness of the epitaxial layer is in a range from 5 μm to 70 μm;
the thickness of the metallization layer is in a range from 1 μm to 20 μm;
the thickness of the connection medium is in a range from 0.5 μm to 50 μm; and
the thickness of the front-side connection body is in a range from 100 μm to 3000 μm.

16. The package of claim 1, wherein the distance between the epitaxial layer and the front-side connection body is less than 20 μm.

17. The package of claim 1, wherein the electronic component is at least one of a semiconductor chip, a transistor chip, a power chip, a vertical chip, a silicon carbide chip, a chip with super-junction, a unipolar chip, a bipolar chip, and a chip in flip-chip configuration.

18. The package of claim 1, wherein the front-side connection body and the electronic component are designed so that stress applied to the electronic component is at least 200 MPa.

19. The package of claim 1, wherein the front-side connection body, the electronic component and an additional carrier on which a back-side of the electronic component is mounted are designed for applying stress to the electronic component at both opposing main surfaces thereof.

20. A method of manufacturing a package, the method comprising:
assembling an at least partially electrically conductive front-side connection body with an electronic component having an epitaxial layer; and
arranging the front-side connection body with respect to the electronic component so that a distance between the epitaxial layer and the front-side connection body is less than 50 μm.

21. The method of claim 20, further comprising at least one of:
heating the electronic component before and/or during the assembling and allowing the electronic component to cool down after the assembling;
bending the electronic component by the assembling;
enhancing stress exerted permanently to the electronic component by the assembling; and
tuning a strain pattern of the electronic component to expose different areas of the electronic component to different strain levels to thereby tune an on-resistance characteristic of the electronic component.
